(19) United States
(12) Patent Application Publication
(10) Pub. No.: US 2011/0011457 A1
(43) Pub. Date: Jan. 20, 2011

(54) SOLAR CELL SYSTEM WITH ENCAPSULANT

(75) Inventors: Edwin Peter Sportel, Arnhem (NL); Willem Jacob Scheerder, Arnhem (NL)

Correspondence Address: OLIFF & BERRIDGE, PLC, P.O. BOX 320850, ALEXANDRIA, VA, 22320-4850, US

(73) Assignee: HELIANTHOS B.V., Arnhem (NL)

(21) Appl. No.: 12/864,676

(22) PCT Filed: Feb. 18, 2009
(86) PCT No.: PCT/EP2009/051918

§ 371 Date: Sep. 24, 2010

(30) Foreign Application Priority Data
Feb. 19, 2008 (EP) 08101766.7

(51) Int. Cl. H01L 31/0203; H01L 31/18; B32B 37/14; B05D 3/00

(52) U.S. Cl. 136/259; 438/64; 156/306.6; 427/372.2; 257/E31.117

(57) ABSTRACT

The present invention is directed to a solar cell system comprising a solar cell on the light-receiving side of which a transparent encapsulant foil is present which comprises a reinforcing layer and two barrier layers, wherein the first, barrier layer is positioned above the reinforcing layer and the second barrier is positioned below the reinforcing layer, determined from the light-receiving side of the solar cell system, wherein the reinforcing layer comprises a fibre-reinforced layer which comprises fibres with an average length of at least 2 cm. The encapsulant foil itself, a process for manufacture thereof, and a process for manufacturing the solar cell system are also claimed.

The present invention pertains to a solar cell system provided with an encapsulant layer, and to a method for manufacturing thereof. The present invention also pertains to a transparent multilayer foil suitable as encapsulant foil for solar cells, and to a method for manufacturing thereof.

Thin film solar cells, also known as thin film photovoltaic cells, generally comprise a carrier and a photovoltaic (PV) layer composed of a semiconductor material provided between a front electrode comprising a transparent conductive oxide (TCO) (on the light-receiving side of the cell) and a back electrode (at the back of the cell). The front electrode is transparent, enabling incident light to reach the semiconductor material, where the incident radiation is converted into electric energy. In this way light can be used to generate electric current, which offers an interesting alternative to, say, fossil fuels or nuclear power.

To improve the resistance of solar cells to the environmental conditions to which they are exposed, they are often provided with a protective layer.

U.S. Pat. No. 5,474,620 describes an encapsulant for solar cells which comprises a repeating stack of glass-fiber layers and layers of a thermoplastic material, the whole being topped off with a F-polymer barrier layer.

U.S. Pat. No. 6,331,673 describes a solar cell encapsulant comprising non-woven glass fiber members, a polymer filler, and a protective film. The bottom side of the solar cell foil is also provided with a filler and an insulation film.

U.S. Pat. No. 5,650,019 describes a photovoltaic element encapsulated in a filler layer, which is covered by a hard resin layer, an adhesive layer, and a barrier layer.

US 2006/0207646 describes the use of a cured liquid silicone in the encapsulation of solar cell modules.

JP2001-068701 discloses a protective sheet which consists of a laminate of a base material with high weatherability, a reinforced fibre-containing resin layer, and optionally a further base layer.

EP1054456 describes various embodiments of protective sheets. The use of reinforcina glass fibers is disclosed.

U.S. Pat. No. 4,369,224 describes the application of a gel coat resin to the top surface of a glass fiber-reinforced layer to increase the weatherability thereof.

The solar cell, systems provided with the encapsulant layer as described in the references cited above still suffer disadvantages. More in particular, there is room for improving the long term resistance of the encapsulant layers against damaging. There is therefore a need for a solar cell provided with an encapsulant foil which shows increased long term resistance against damaging and against the long term influence of environmental conditions.

The present invention provides such a solar cell system. The solar cell system according to the invention comprises a solar cell (1), on the light-receiving side of which a transparent encapsulant foil (2) is present, which comprises a reinforcing layer (3) and two barrier layers, wherein the first barrier layer (4) is positioned above the reinforcing layer and the second barrier layer (5) is positioned below the reinforcing layer, determined from the light-receiving side of the solar cell system, wherein the reinforcing layer comprises a fibre-reinforced layer which comprises fibres with an average length of at least 2 cm.

It has been found that an encapsulant foil characterised by the above parameters combines a good long term resistance against damaging and against the long term influence of environmental conditions. Further, the use of fibres with the specified length leads to a high stiffness and dimensional stability, in particular in the case of woven materials. The use of fibres with the specified length will also lead to less fibrils or other loose fibre ends. This leads to improved processing and less dust formation.

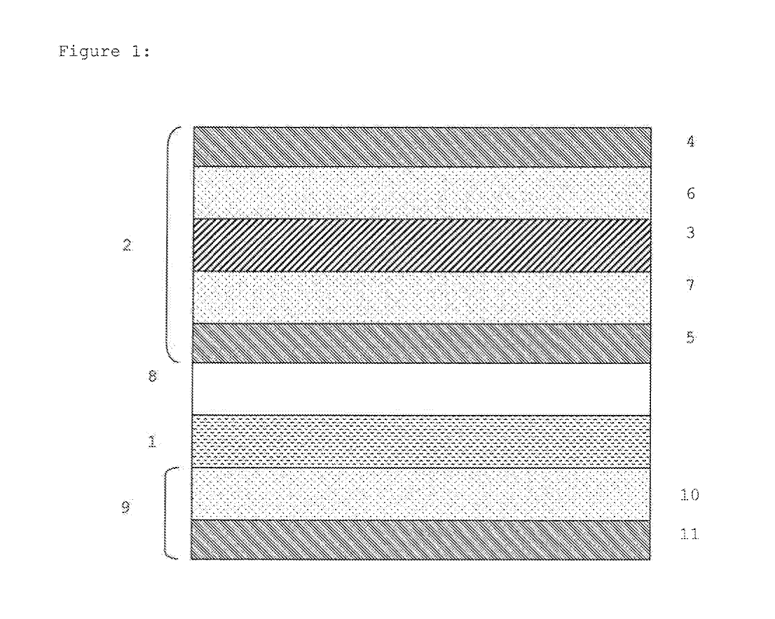

FIG. 1 illustrates one embodiment of the present invention. The present invention should not be considered limited thereto or thereby. In this FIGURE, (1) refers to the thin film solar cell, which comprises a TCO layer, a PV layer, a back electrode layer, and optional other components, e.g., a carrier (all not illustrated). (2) refers to the transparent encapsulant foil. (3) refers to the reinforcing layer in the encapsulant foil; (4) refers to the first barrier layer of the encapsulant foil, which is positioned above the reinforcing layer, determined from the light-receiving side of the solar cell system. (5) refers to the second barrier layer of the encapsulant foil, which is positioned below the reinforcing layer, determined from the light-receiving side of the solar cell system. (6) refers to the (optional) intermediate layer present between the first barrier layer and the reinforcing layer, co refers to the (optional) intermediate layer present between the second barrier layer and the reinforcing layer. (8) refers to the (optional) adhesive layer, which is intended to adhere the transparent encapsulant foil (2) to the solar cell (1). (9) refers to the (optional) protective foil on the back of the solar cell system, which, in the illustrated embodiment is made up of an intermediate layer (10) and a barrier layer (11).

The solar cell system of the present invention has an increased long-term resistance against damaging and against the long-term influence of environmental conditions. This is due to the presence of a barrier layer both above and below the reinforcing layer. In the prior art systems, which comprise a barrier above a reinforcing layer, the barrier layer is present to protect the system from environmental conditions, e.g., the entrance of water. The reinforcing layer is intended to protect the underlying solar cell against damages caused by impacting objects, e.g., hailstones or other impacting objects. In the prior art system, an impacting object will be stopped from damaging the solar cell by the reinforcing layer. However, the barrier layer is by then already damaged, and this leaves the system open for the ingress of environmental substances such as water. In contrast, in the system of the present invention, when an impacting object has damaged the first barrier layer and is stopped by the reinforcing layer, the second barrier layer is still intact, and protects the solar cell from environmental substances and provides the required electrical safety. Further, the presence of a transparent encapsulant foil which comprises a reinforcing layer increases the mechanical stability and total strength of the product. Additionally, it will decrease the mechanical load on the solar cell itself. In particular, when the solar cell system is flexible, the presence of a transparent encapsulant foil which comprises a reinforcing layer will help to improve the bending properties of the foil by bringing the force carrier capacity on both sides of the solar cell more in balance. This will improve the strength and flexibility properties of the product for production, storage, transport and installation.

Other advantages of the present invention and of particular embodiments thereof will become apparent from the following specification.

Obviously, the encapsulant foil used in the present invention needs to be transparent. Within the context of the present invention the word transparent means at least transparent for light of the wavelength used by the photovoltaic layer to generate electricity. The transparency of the encapsulant foil, and any other layers which are between the solar cell and the light source, is selected such that at least 50% of the light with this wavelength which falls onto the solar cell system reaches the photovoltaic layer in the solar cell, 1.0 preferably at least 70%, more preferably at least 80%.

The reinforcing layer used in the encapsulant foil of the present invention is a fibre-reinforced layer which comprises fibres with an average length of at least 2 cm. More in particular, the fibres have a length of at least 4 cm, more in particular at least 8 cm. For further specification of the fibre length reference is made to the specific embodiments that will be elucidated below.

The fibre layer in the fibre-reinforced layer generally has a fibre weight/area of between 10 and 300 gram/m2, in particular between 15 and 100 gram/m2, more in particular between 15 and 75 gram/m2. It is noted that these values are for the fibre weight per area, excluding any matrix material present in the fibre-reinforced layer.

In one embodiment of the present invention, the fibre-reinforced layer has a homogeneous surface density over the solar cell system. That is, the difference in fibre weight per area of the fibre-reinforced layer in the solar cell system between the area (of one cm2) with the highest density and the area (of one cm2) with the lowest density is less than 20%, calculated on the average fibre weight per area, more in particular less than 10%.

The fibres generally have a thickness in the range of 1 to 20 micron, in particular 2 to 15 micron, more in particular 2 to 10 micron.

In one embodiment of the present invention, the fibre-reinforced layer comprises a non-woven fibre layer. The fibres in the non-woven layer generally have a length of at least 2 cm, more in particular at least at least 4 cm, still more in particular at least 8 cm. The maximum fibre length is not critical in this embodiment and will depend on the non-woven manufacturing process. In general longer fibres are preferred because they will contribute more to the mechanical stability of the solar cell system.

In another embodiment of the present invention, the fibre-reinforced layer comprises a woven fibre layer. The fibre length will generally correspond to the width, respectively, the length of the reinforcing layer, and will therefore generally vary between 15 cm and 2 meters for the as fibres in the direction of the width of the solar cell system, and between 15 cm and infinite for fibres in the direction of the length of the solar cell system, where infinite means very large and will be attained when the solar cell system is manufactured via a continuous roll-to-roll process. It is noted that the use of a fibre-reinforced layer which comprises a woven fibre layer is a preferred embodiment of the present invention in comparison with the use of a non-woven as described above, where the fibres are oriented more or less random, the use of oriented fibres in a woven arrangement will allow for a higher stiffness to be obtained.

In a further embodiment of the present invention, the fibre-reinforced layer comprises a stack of at least two monolayers of oriented fibres, each monolayer containing unidirectionally oriented reinforcing fibres, wherein the fibre direction in each monolayer is rotated with respect to the fibre direction in an adjacent monolayer. In a preferred embodiment, the fibre direction between adjacent monolayers is rotated with an angle of 90), to form a so-called cross-ply. The number of monolayers in the stack is at least 2, and generally at most 12. More in particular, the number of monolayers in the stack is between 2 and 6, in one embodiment, the fibres have a length in the range mentioned above for the fibres used in non-wovens. In another embodiment, the fibres will have a length as specified above for the fibres in a woven layer.

The purpose of the reinforcing layer is to increases the resistance of the solar cell system against the impact of external objects, and at the same time provide mechanical stability to the solar cell system. Obviously, the transparency of the layer should be such that the final encapsulant foil is transparent. In a preferred embodiment the reinforcing layer will also contribute to the mechanical stability of the solar cell system, without necessarily detracting from the flexibility of the system in the case that the solar cell itself is flexible.

The fibre-reinforced layer generally has a stiffness per unit width of at least 100 kN/m, more in particular at least 500 kN/m, most preferably at least 1500 kN/m. These values apply over the full temperature range between −40° C. and +90° C. Accordingly, the fibre-reinforced layer has a stiffness per unit width at 80° C. of at least 100 kN/m, more in particular at least 500 kN/m, most preferably at least 1500 kN/m.

The encapsulant foil, encompassing the fibre-reinforced layer the two barrier layers, and optionally intermediate layers, also generally has a stiffness per unit width of at least 100 kN/m, more in particular at least 500 kN/m, most preferably at least 1500 kN/m. These values apply over the full temperature range between −40° C. and +90° C. Accordingly, the encapsulant foil has a stiffness per unit width at 80° C. of at least 100 kN/m, more in particular at least 500 kN/m, most preferably at least 1500 kN/m.

For the fibre-reinforced layer, the stiffness per unit width is calculated by determining the modulus of the fibre-reinforced layer, in accordance with, e.g., ASTM 13039, and multiplying it by the thickness of the fibre-reinforced layer.

For the encapsulant foil, the stiffness per unit width is calculated by determining the modulus of the encapsulant foil, in accordance with, e.g., ASTM D3039, and multiplying it by the thickness of the encapsulant foil.

The nature of the fibres used in the reinforcing layer is not limiting as long as the required values as to transparency and physical properties are met. The use of a layer comprising glass fibers is considered preferred because of the suitable physical and chemical properties, transparency, and relatively low cost associated with the use of glass. A specific advantage of using a reinforcing layer comprising glass fibers is as follows. The low thermal expansion and high strength of glass reinforcing material as compared to the polymer components of the encapsulant foil causes a reduction of the total thermal expansion of the solar cell. This is advantageous, because the thermal expansion of the solar cell itself is much lower than that of polymer material. A reduction of the thermal strain difference between the highly inelastic and fragile solar cell itself and the average expansion of the solar cell system significantly reduces the mechanical load change on the solar cell itself during temperature changes. This results in a reduction in failure behaviour from fatigue and increases the reliability and lifetime of the solar cell system.

In one embodiment, the reinforcing layer comprises 10-80 wt. % of a matrix material. The matrix material is a polymer material which serves one or more of a number of purposes. One purpose of the matrix material may be to adhere the fibres together. This is of particular importance where the reinforcing layer comprises a stack of monolayers of oriented fibres. In one embodiment, it may be preferred for the reinforcing layer to contain between 15 and 80 wt. %, preferably between 20 and 70 wt, %, more preferably between 30 and 70 wt. % of a matrix material.

The matrix material may be any polymer material which is able to fulfil the above requirements. It is within the scope of the skilled person to select a suitable material. It may comprise a thermoplastic or thermosetting polymer. Suitable polymers are known in the art and comprise, for example, ethylene vinyl acetate (EVA), thermoplastic polyolefins (TPOs), silicone polymers, thermoplastic polyurethanes, polyurethane rubbers (PUR), and polyvinyl butyral (PVB). It has been found that the use of silicone polymers is particularly attractive in the present invention due to, int. al., their high UV stability, their low processing temperature, their high Tg, the fact that they show no yellowing when subjected to UV radiation, and their high impermeability to water. Of the silicone polymers, both thermoplastic, that is, non-curable, and thermosetting, that is, curable polymers may be used. The use of curable silicone polymer may be preferred, int. al., because they enable the use of a particularly attractive manufacturing process for the encapsulant foil, as will be discussed in more detail below.

In one embodiment, the properties of the matrix material are matched to the properties of the fibres. More in particular, in one embodiment, between 15 and 80 wt. %, preferably between 20 and 70 wt. %, more preferably between 30 and 70 wt. % of a matrix is used and the refractive index of the matrix material is matched to be within 30%, preferably within 20%, more preferably within 10%, still more preferably within 5%, of the refractive index of the reinforcing fibres. This matching of refractive index leads to a reinforcing layer with increased transparency. In this embodiment it is preferred for the fibres to be embedded in the matrix material. When the reinforcing fibers are glass, it is preferred to use a silicone resin, in particular a phenyl-based silicone resin, as this will allow matching of the refractive indices as described above while at the soma time benefiting from the advantages of silicone resins as described above.

The thickness of the reinforcing layer is generally at least 8 microns, more in particular at least 20 microns, still more in particular at least 30 microns. The thickness of the reinforcing layer is generally at most 500 microns, more in particular at most 200 microns, still more in particular at most 100 microns.

The barrier layers used in the present invention may be the same or different. They are intended to protect the solar cell from the effect of environmental conditions, in particular from the ingress of water. Further, they should be electrically insulating, anti-soiling and have adequate resistance to degradation under the conditions prevailing during use of the solar cell, and have sufficient integrity to seal and protect the underlying layers. Obviously, their transparency should be such that the final encapsulant foil has the required transparency.

The second barrier layer, that is, the barrier layer below the reinforcing layer generally has an insulation resistance of at least 40 MOhm*m2 at a test voltage of (2000V+4 times the maximum system voltage, as defined in IEC61730-2, test MST16.

In principle, any polymeric material which meets the above requirements is suitable for use in the barrier layers of the present invention. It is within the scope of the person skilled in the art to select a suitable polymer. The following is given as guideline only. Suitable polymers include polyesters such as polyethylene terephthalate (PET) or polyethylene naphthenate (PEN), polycarbonates, polymethyl methacrylate, polyimide, polyphenylene sulphide and fluoropolymers.

One particularly attractive group of polymeric materials are the fluoropolymers, in particular when the solar cell system is intended for long term outdoor use. These materials are transparent, highly inert, and resistant to soiling. Suitable fluoropolymers are commercially available and include copolymers of ethylene and tetrafluoroethylene (ETFE), polytetrafluoroethylene (PTFE), polyvinylidene fluoride (PVDF), fluorinated ethylene propylene copolymers (FEP), tetrafluoroethylene-hexafluoropropylene-vinylidene fluoride terpolymers (THV), tetrafluoroethylene based perfluorinated polymers using monomers such as hexafluoropropene (HFP), perfluoroalkoxyethylene (PEA) and perfluoromethylvinylether and EFEP (a transparent terpolymer, consisting of ethylene, tetrafluoroethylene (TFE) and hexafluoropropylene (HFP).

The barrier layers generally have a thickness of at least 10 microns, more in particular a thickness of at least 17 microns, still more in particular of at least 25 microns. The thickness of the barrier layers is generally at most 500 microns, more in particular at most 200 microns, still more in particular at most 100 microns.

The presence of barrier layers has an additional advantage, namely the protection of the fragile layers of the solar cell from the stiff reinforcing layer. The reinforcing layer distributes a load over the large area which reduces the local stress perpendicular to the surface of the solar cell. This leads to a reduction of the risk of local failure of the solar cell. However, if the reinforcing layer is damaged locally, the second barrier layer between the reinforcing layer and the solar cell serves not only as a chemical barrier but also as a mechanical barrier by elastically absorbing the energy of the stiff sharp point load of broken reinforcing material.

In one embodiment of the present invention, the encapsulant foil additionally comprises an intermediate layer (6) between the reinforcing layer and the first barrier layer, or an intermediate layer (7) between the reinforcing layer and the second barrier layer. In a particularly preferred embodiment intermediate layers (6) and (7) are both present. The purpose of the intermediate layer or layers is to increase the integrity of the encapsulant foil by increasing the adherence of the layers to each other.

The intermediate layer may be made up of any polymer material which is able to fulfil the above requirements. It is within the scope of the skilled person to select a suitable material. For examples of suitable polymers I refer to what has been stated above for the matrix of the reinforcing layer. Again, the use of one or more silicone intermediate layers in combination with a glass-fibre reinforced layer may be preferred.

The intermediate layers, which may be the same or different, generally have a thickness of at least 3 microns, more in particular a thickness of at least 5 microns, still more in particular of at least 8 microns. The thickness of the intermediate layers is generally at most 100 microns, more in particular at most 60 microns, still more in particular at most 40 microns.

The total thickness of the encapsulant foil in the present invention generally is at least 40 microns, more in particularly at least 50 microns, more in particular at least 70 microns. The total thickness of the encapsulant foil in the present invention generally is at most 1700 microns, more in particularly at most 1200 microns, more in particular at most 800 microns. Embodiments with a thickness of at most 400 microns or at most 300 microns may also be envisaged, and sometimes preferred.

It has been found that the encapsulant foil of the present invention has increased long term performance. More in particular, it has been found that the transmission in the 500-1100 nm wavelength range of the encapsulant foil of the present invention, after 1000 hours damp heat test (85° C. and 85% RH) and 600 hours UVA test, decreases with less than 5%, as compared to the foil before testing. Preferably, this also applies to the transmission in the 400-1.400 nm wavelength range, more preferably also to the transmission in the 350-1600 nm wavelength range.

It is noted that, as indicated above, the crux of the present invention is that the encapsulant foil encompasses a reinforcing layer and a barrier layer above the reinforcing layer and a barrier layer below the reinforcing layer, determined from the light-receiving side of the solar cell unit, wherein the reinforcing layer meets specific properties. It is within the scope of the present invention to have two or more reinforcing layers present between the barrier layers, if so desired combined with one, two, or more intermediate layers. It is further possible in principle to have a further reinforcing layer present below the second barrier layer. However, this is generally not required.

In the present invention the encapsulant foil is present above the light-receiving side of a solar cell. In a preferred embodiment the encapsulant foil, is adhered to the light-receiving side of the solar cell using an adhesive (see adhesive layer (2) in FIG. 1). The adhesive may be any transparent adhesive which is capable of adhering the solar cell system to the encapsulant foil. The adhesive should be durable, and able to withstand environmental influences. Suitable adhesives include thermosetting and thermoplastic adhesives. Suitable adhesives include polyurethane rubber, in particular aliphatic polyurethane rubber, silicones, ethylene vinyl acetate (EVA), thermoplastic polyolefins (TPOs), and polyvinyl butyral (PVB).

In one embodiment the adhesive is a silicone based adhesive. These materials have been found to be transparent, colorless, inert, durable, and able to withstand the conditions prevailing during use of the solar cell system. The use of a curable adhesive has been found to be particularly attractive, int. al., because, as will be elucidated below, allows the easy manufacture of the system according to the invention.

In general, the adhesive layer has a thickness of at least 2 microns, more in particular a thickness of at least 5 microns. In some cases, the surface of the solar cell may not be completely flat, due to, for example, the presence of a series connection, of busbars, or of other components. If this is the case it may be attractive for the adhesive layer to be thick enough to even out the difference in height. In that case, the adhesive layer may have a thickness of at least 50 microns, more in particular at least 100 microns, in some cases at least 125 microns, depending on the thickness of the components to be encapsulated.

The maximum thickness of the adhesive layer is not critical to the present invention and could be as thick as up to 500 microns, while values up to 200 microns would be more conventional.

The nature of the solar cell that is combined with the encapsulant foil in the present invention is not critical. They will generally comprise a back electrode, a photovoltaic layer, and most often a transparent front electrode based on a transparent conductive oxide, often indicated as TCO layer. Other conventional elements of solar cells may also be present such as barrier layers, series connections, busbars, carrier layers below the back electrode, protective layers above the TCO, etc. The various components of solar cells are known in the art and require no further elucidation here.

A type of solar cell to which the present invention is of particular use are the solar cells where the photovoltaic layer, or where present the TCO layer, is not covered with a transparent overlayer, e.g., a transparent glass plate or the like. Solar cells which are particularly suitable for use in the present invention are flexible solar cell foils comprising, from the light-incident side down, a TCO layer, a PV layer, a back electrode layer, and a flexible substrate. Suitable solar cell foils are described, for example in WO98/13882, WO99/49483, WO01/47020, WO01/78156, WO03/001602, WO03/075351, and WO2005/015638 the disclosures of which as regards the nature of the various components of the solar cells are incorporated herein by reference.

The application of a flexible solar cell foil in the present invention is so attractive because the present invention allows the encapsulation of such a solar cell system while maintaining its flexibility.

In one embodiment of the present invention a flexible solar cell foil comprising from the light-receiving side down a TCO layer, a photovoltaic layer, a back electrode layer, and a flexible substrate is encapsulated with an encapsulant foil as discussed above on the light-receiving side of the solar cell, foil, and with a protective foil on the non-light-receiving side of the solar cell. In one embodiment, the protective foil comprises comprising an intermediate layer and a barrier layer. In another embodiment the protective foil comprises a reinforcing layer and two barrier layers, wherein the first barrier layer is positioned on one side of the reinforcing layer and the other is positioned on the other side of the reinforcing layer. In this embodiment the protective foil may be an encapsulant foil as described in detail above, including, if so desired intermediate layers.

For the properties of the layers reference is made to what has been discussed above.

The protective foil may be combined with the solar cell system using an adhesive layer, e.g., as specified above.

In general it is noted that the transparent encapsulant foil described above may also be suitable for application on the non-light receiving side of a solar cell, for providing protection thereto. The protective foil may be combined with the solar cell system using an adhesive layer, e.g., as specified above.

In one embodiment, the encapsulant foil suitable for use in the solar cell system according to the invention can be manufactured as follows. The reinforcing layer is sandwiched between two barrier layer foils, and the combination is subjected to a pressure step to adhere the layers to each other. The presence of an adhesive intermediate layer is however preferred.

Where intermediate layers are present between the barrier layers and the reinforcing layers, the process may, in one embodiment, be carried out as follows. In a first step, the polymer that will provide the intermediate layer is applied onto a foil of the barrier layer, either by a lamination process where the intermediate layer polymer is already in the form of a foil, or by an appropriate spreading process where the polymer is in liquid form. The reinforcing layer is applied onto the polymer, and the layer set is combined with the second barrier layer which has previously been provided with the polymer that will provide the intermediate layer. Where the intermediate layer is curable, the total layer set is then subjected to a curing step to cure the intermediate layer polymer. In a preferred embodiment the foil is manufactured via a roll-to-roll process.

The encapsulant foil may be combined with the solar cell by a lamination process if an adhesive layer is present, either the solar cell or the encapsulant foil, or both, are covered with the adhesive, and the encapsulant foil is adhered to the solar cell. Where the adhesive needs to be cured, a curing step is carried out. Where the solar cell is a flexible solar cell foil, this process can, in a preferred embodiment, be carried out in the form of a roll-to-roll process.

The flexibility of a solar cell foil, before and after encapsulation, may be expressed by the curvature (defined as the inverse bending radius [1/m]). A curvature of null m−1 represents a perfectly flat laminate. The positive and negative curvature represent bending the solar cell laminate with the light receiving side on the outside and inside, respectively.

For flexible solar cell systems according to the invention it is preferred that after encapsulation the maximum curvature, defined as the inverse bending ratio above which the solar cell breaks down, is at least 2 m−1, more preferably at least 10 m−1, still more preferably at least 40 m−1. In some cases a maximum curvature of at least 100 m−1 may be obtained. It is a surprising feature of the present invention that the maximum curvature of the solar cell system may be higher than that of the solar cell itself. This is because the presence of the encapsulation layer reduces the stress on the solar cell during bending.

As indicated above, in this embodiment it may be attractive to apply a back encapsulant layer comprising an intermediate layer and a barrier layer. The application of the back encapsulant can be integrated in the above process.

When used in a solar cell foil the cured encapsulant layer is combined with a solar cell foil, while on the other side of the solar cell foil a foil comprising a barrier layer and an intermediate layer may be applied.

1. A solar cell system comprising a solar cell on the light-receiving side of which a transparent encapsulant foil is present which comprises a reinforcing layer and two barrier layers, wherein the first barrier layer is positioned above the reinforcing layer and the second barrier is positioned below the reinforcing layer, determined from the light-receiving side of the solar cell system, wherein the reinforcing layer comprises a fibre-reinforced layer which comprises fibres with an average length of at least 2 cm.

2. Solar cell system according to claim 1 wherein an adhesive layer is present between the solar cell and the encapsulant foil.

3. Solar cell system according to claim 1 wherein at least one of the barrier layers is a layer of a fluoropolymer.

4. Solar cell system according to claim 1 wherein the fibres in the fibre-reinforced layer are glass fibers.

5. Solar cell system according to claim 1 wherein the fibre-reinforced layer comprises a non-woven fibre layer, a woven fibre layer, or a stack of at least two monolayers of oriented fibres, each monolayer containing unidirectionally oriented reinforcing fibres, wherein the fibre direction in each monolayer is rotated with respect to the fibre direction in an adjacent monolayer.

6. Solar cell system according to claim 1, wherein the fibre-reinforced layer has a fibre weight/area of between 10 and 300 gram/m2.

7. Solar cell system according to claim 1 wherein the reinforcing layer comprises 10-80 wt. % of a matrix, material.

8. Solar cell system according to claim 1 wherein in the encapsulant foil an interme-diate layer is present between the reinforcing layer and the first barrier layer, between the reinforcing layer and the second barrier layer, or between the reinforcing layer and both the first and second barrier layers.

9. Solar cell system according to claim 8 wherein the fibre-reinforced reinforcing layer comprises between 15 and 80 wt. %, of a matrix and the refractive index of the matrix material is matched to be within 30% of the refractive index of the reinforcing fibres.

10. Process for manufacturing a solar cell system according to claim 1 wherein a transparent encapsulant foil which comprises a reinforcing layer and two barrier layers, wherein the first barrier layer is positioned above the reinforcing layer and the second barrier is positioned below the reinforcing layer, is applied on the light-receiving side of a solar cell.

11. Process according to claim 10 wherein a back encapsulant layer is applied to the non-light receiving side of the solar cell, before, after, or simultaneous with the application of the encapsulant foil.

12. Process according to claim 10 wherein the transparent encapsulant foil is laminated to the solar cell from a roll.

13. Process according to claim 10 wherein a back encapsulant layer is applied to the non-light receiving side of the solar cell, before, after, or simultaneous with the application of the encapsulant foil.

14. Transparent encapsulant foil suitable for the encapsulation of solar cell which comprises sequentially a first barrier layer, a first intermediate layer, a reinforcing layer, a second intermediate layer, and a second barrier layer, wherein the reinforcing layer comprises a fibre-reinforced layer which comprises fibres with an average length of at least 2 cm.

15. Process for manufacturing a transparent encap-sulant foil according to claim 14, which comprises the steps of providing the polymer that will provide the intermediate layer onto a foil of the barrier layer, either by a lamination process where the intermediate layer polymer is already in the form of a foil, or by an appropriate spreading process where the polymer is in liquid form, applying the reinforcing layer onto said polymer, combining the layer set with the second barrier layer which has previously been provided with the polymer that will provide the intermediate layer, and, where the intermediate layer is curable, subjecting the total layer set to a curing step to cure the intermediate layer polymer.
